(19) United States
(12) Patent Application Publication
(10) Pub. No.: US 2023/0318325 A1
(43) Pub. Date: Oct. 5, 2023

(54) PORTABLE POWER BANK WITH DIGITAL DISPLAY

(71) Applicant: Consilium Enterprises, Inc., Los Angeles, CA (US)

(72) Inventor: Paolo Del Vecchio, Los Angeles, CA (US)

(73) Assignee: Consilium Enterprises, Inc., Los Angeles, CA (US)

(21) Appl. No.: 17/693,086

(22) Filed: Mar. 11, 2022

(51) Int. Cl. H02J 7/00; H02J 7/35; H05K 5/00; H05K 7/14; H05K 5/02

(52) U.S. Cl. CPC H02J 7/0042; H02J 7/35; H05K 5/0017; H05K 5/0217; H05K 7/1427

(57) ABSTRACT

A portable power bank with a digital display comprising: a housing; a power source; and a digital display; wherein the housing comprises or contains a circuit board that may be configured to allow desired images and videos to be shown on the digital display, and communicate with a remote electronic device, such that a user may determine what images or video to display on the digital display.

### FIELD OF DISCLOSURE

The present disclosure relates to portable power banks configured to operate as electronic accessories. More specifically, the present disclosure relates to a power bank with an outward facing digital display embedded in or on the surface of the power bank, such that the display may be configured to display videos, pictures, graphics, information, gifs, and other moving or static images.

### BACKGROUND

Digital accessories and the are commonplace in today’s society, with most individuals having access to a smartphone, among other electronics, at all times. In addition, many individuals also carry other accessories for their daily life, such as a power bank to be able to charge their portable electronics when there is no access to an outlet or charging station.

Many individuals who carry power banks with them may enjoy customizing their power bank with decorative components to express themselves. Additionally, personalization also has the benefit of making an owner’s power bank distinct and easy to identify, which may be important because there are a relatively limited number of styles of popular power banks.

Therefore, a need exists for power banks that incorporate electronic components to allow users to customize their power banks and/or broadcast messages to onlookers.

### SUMMARY

The following presents a simplified overview of the example embodiments in order to provide a basic understanding of some embodiments of the example embodiments. This overview is not an extensive overview of the example embodiments. It is intended to neither identify key or critical elements of the example embodiments nor delineate the scope of the appended claims. Its sole purpose is to present some concepts of the example embodiments in a simplified form as a prelude to the more detailed description that is presented hereinbelow. It is to be understood that both the following general description and the following detailed description are exemplary and explanatory only and are not restrictive.

One embodiment may be a portable power bank comprising: a housing; a power source; and a first digital display; wherein the first digital display is configured to display one or more data files; and wherein the power source is configured to charge one or more electronic devices connected to the portable power bank. The power bank may further comprise a first display cover; wherein the first display cover may be configured to protect the first digital display by substantially covering the first digital display; and wherein the first display cover may be transparent. The power bank may further comprise a second digital display. The power bank may further comprise a circuit board; wherein the circuit board may comprise a charging module, a display control, and a power switch; wherein the circuit board is powered by the power source. The circuit board may comprise a wireless communication module. The wireless communication module may be configured to receive one or more electronic signals from a remote electronic device. The one or more electronic signals may comprise one or more of one or more data files, one or more instructions, and combinations thereof. The one or more data files may comprise one or more of the following: videos, pictures, images, graphics, information, gifs, and combinations thereof. The power source is located substantially within the housing; and wherein the circuit board is located substantially within the housing. Preferably, the power source may be a battery. The battery may be substantially enclosed in fireproof foam. The one or more instructions may be configured to cause one or more data files to be displayed on the first digital display. The housing may have a plurality of sides comprising at least a first side and a second side; wherein the first digital display substantially covers the first side. The first digital display may substantially cover the first side and the second side. The second side may at least partially be covered by a second digital display. The plurality of sides may comprise the first side, the second side, a third side, and a fourth side; wherein the first digital display substantially covers the first side, the second side, the third side, and the fourth side. The power bank may further comprise at least one solar panel; wherein the at least one solar panel may be configured to charge the power source.

Another embodiment may be a portable power bank comprising: a housing; a power source; a circuit board; a first digital display; and a display cover; wherein the housing comprises at least a first side and a second side; wherein the first digital display covers at least a portion of the first side; wherein the display cover is configured to protect the first digital display by substantially covering the first digital display; wherein the display cover is transparent; wherein the circuit board comprises a charging module, a display control, a wireless communication module, and a power switch; wherein the circuit board and the first digital display are powered by the power source; wherein the wireless communication module is configured to receive one or more electronic signals from a remote electronic device; herein the one or more electronic signals comprise one or more of one or more data files, one or more instructions, and combinations thereof; wherein the one or more data files comprise one or more of the following: videos, pictures, images, graphics, information, gifs, and combinations thereof; wherein the power source is substantially contained within the housing; wherein the circuit board is substantially contained within the housing; wherein the power source is a battery; and wherein the one or more instructions are configured to cause one or more data files to be displayed on the first digital display. The housing may have a plurality of sides comprising at least a first side and a second side; wherein the first digital display substantially covers the first side. The second side may be at least partially covered by a second digital display. The plurality of sides may comprise the first side, the second side, a third side, and a fourth side; wherein the first digital display substantially covers the first side, the second side, the third side, and the fourth side.

In accordance with the embodiments disclosed herein, the present disclosure is directed to a power bank with a digital display.

The system of the present disclosure may comprise a power bank combined with a digital display, a power source, and a circuit board, in order to capitalize on the preferred characteristics of both a power bank and a digital accessory.

The power bank of the present disclosure may comprise a battery that may be internally encased in fireproof foam to protect the battery pack from accidental dropping and other potential damage. The circuit board may comprise a charging module, a display control, and a power switch. The power bank may also comprise a battery status indicator, such as a light having different intensities or colors to represent charge level of the battery. The circuit board may control the digital display, and may be powered by the battery.

In one embodiment, the circuit board may further comprise a wireless control device, such as a radio frequency identification device (RFID) and short-range wireless interconnection. This may allow a user to remotely control what may be displayed on the digital display. Additionally, the wireless control device may allow a user to remotely turn the digital display on and off.

In another embodiment, the circuit board may further comprise a central processing unit (CPU), a video processor (GPU), and memory storage device, such as a solid-state memory storage device. This may allow a user access to greater processing power and increased functionality of the device for display of photos, videos, gifs, information, and the like.

In another embodiment, the digital display may be SMB LEDs, and individual LED diodes. In another embodiment, the digital display may be LED diodes in the format of a panel. In other embodiments, the digital display may be OLED screens, plasma screens, and full array LED screens. In other embodiments, the digital display may be an EL panel. It is understood that different types of digital displays may be selected for optimized performance under particular conditions.

In another embodiment, the display cover may be a transparent material configured to allow light to pass through. The display cover may be molded plastic, clear molded epoxy, or solid molded epoxy. Different materials may be utilized depending on particular qualities desired.

In another embodiment, the charging module may comprise a charging port such as micro-USB, Apple 40 pin/lightening, USB-C charging port, and/or a solar charger. The different types of charging ports may allow for compatibility with a consumer’s existing charging hardware, so that the power bank may be charged with pre-existing cables. In another embodiment, the charging module may be a wireless inductive charging system. The charging module and ports allow the battery or power source to be charged and recharged to allow the digital display the power needed to perform.

Still other advantages, embodiments, and features of the subject disclosure will become readily apparent to those of ordinary skill in the art from the following description wherein there is shown and described a preferred embodiment of the present disclosure, simply by way of illustration of one of the best modes best suited to carry out the subject disclosure. As it will be realized, the present disclosure is capable of other different embodiments and its several details are capable of modifications in various obvious embodiments all without departing from, or limiting, the scope herein. Accordingly, the drawings and descriptions will be regarded as illustrative in nature and not as restrictive.

### BRIEF DESCRIPTION OF THE DRAWINGS

The drawings are of illustrative embodiments. They do not illustrate all embodiments. Other embodiments may be used in addition or instead. Details which may be apparent or unnecessary may be omitted to save space or for more effective illustration. Some embodiments may be practiced with additional components or steps and/or without all of the components or steps which are illustrated. When the same numeral appears in different drawings, it refers to the same or like components or steps.

FIG. 1 is an illustration of a perspective view of one embodiment of a portable power bank with a digital display.

FIG. 2 is an illustration of a perspective view of another embodiment of a portable power bank with a digital display.

FIG. 3 is an illustration of a perspective view of another embodiment of a portable power bank with a digital display.

FIG. 4 is an illustration of a cross-section view of one embodiment of a power bank with a digital display.

FIG. 5 is a diagram of one embodiment of a portable power bank with one or more digital displays.

FIG. 6 is an illustration of a top view of one embodiment of a portable power bank.

FIG. 7 is an illustration of a side view of one embodiment of the portable power bank.

FIG. 8 is an illustration of an end view of one embodiment of the portable power bank.

FIG. 9 is an illustration of an end view of another embodiment of the portable power bank.

FIG. 10 is an illustration of an end view of another embodiment of the portable power bank.

### DETAILED DESCRIPTION OF THE ILLUSTRATIVE EMBODIMENTS

In the following detailed description of various embodiments, numerous specific details are set forth in order to provide a thorough understanding of various aspects of the embodiments. However, these embodiments may be practiced without some or all of these specific details. In other instances, well-known methods, procedures, and/or components have not been described in detail so as not to unnecessarily obscure aspects of the embodiments.

While multiple embodiments are disclosed, still others will become apparent to those skilled in the art from the following detailed description. As will be realized, these embodiments are capable of modifications in various obvious aspects, all without departing from the spirit and scope of protection. Accordingly, the graphs, figures, and the detailed descriptions thereof, are to be regarded as illustrative in nature and not restrictive. Also, the reference or non-reference to a particular embodiment shall not be interpreted to limit the scope of protection.

In the following description, certain terminology is used to describe certain features of one or more embodiments. For purposes of the specification, unless otherwise specified, the term “substantially” refers to the complete or nearly complete extent or degree of an action, characteristic, property, state, structure, item, or result. For example, in one embodiment, an object that is “substantially” located within a housing would mean that the object is either completely within a housing or nearly completely within a housing. The exact allowable degree of deviation from absolute completeness may in some cases depend on the specific context. However, generally speaking, the nearness of completion will be so as to have the same overall result as if absolute and total completion were obtained. The use of “substantially” is also equally applicable when used in a negative connotation to refer to the complete or near complete lack of an action, characteristic, property, state, structure, item, or result.

As used herein, the terms “approximately” and “about” generally refer to a deviance of within 5% of the indicated number or range of numbers. In one embodiment, the term “approximately” and “about,” may refer to a deviance of between 0.0001-40% from the indicated number or range of numbers.

As used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are signify both in relation to the other endpoint, and independently of the other endpoint.

“Optional” or “optionally” means that the subsequently described event or circumstance may or may not occur, and that the description includes instances where said event or circumstance occurs and instances where it does not.

Throughout the description and claims of this specification, the word “comprise” and variations of the word, such as “comprising” and “comprises,” means “including but not limited to,” and is not intended to exclude, for example, other components, integers or steps. “Exemplary” means “an example of” and is not intended to convey an indication of a preferred or ideal embodiment. “Such as” is not used in a restrictive sense, but for explanatory purposes.

Disclosed are components that may be used to perform the disclosed methods and systems. These and other components are disclosed herein, and it is understood that when combinations, subsets, interactions, groups, etc. of these components are disclosed that while specific reference of each various individual and collective combinations and permutation of these may not be explicitly disclosed, each is specifically contemplated and described herein, for all methods and systems. This applies to all embodiments of this application including, but not limited to, steps in disclosed methods. Thus, if there are a variety of additional steps that may be performed it is understood that each of these additional steps may be performed with any specific embodiment or combination of embodiments of the disclosed methods.

The present methods and systems may be understood more readily by reference to the following detailed description of preferred embodiments and the examples included therein and to the Figures and their previous and following description.

Various embodiments are now described with reference to the drawings. In the following description, for purposes of explanation, numerous specific details are set forth in order to provide a thorough understanding of one or more embodiments. It may be evident, however, that the various embodiments may be practiced without these specific details. In other instances, well-known structures and devices are shown in block diagram form to facilitate describing these embodiments. It is to be understood that the methods and systems are not limited to specific methods, specific components, or to particular implementations. It is also to be understood that the terminology used herein is for the purpose of describing particular embodiments only and is not intended to be limiting.

Embodiments of the present disclosure generally relate to the field of power banks with digital displays.

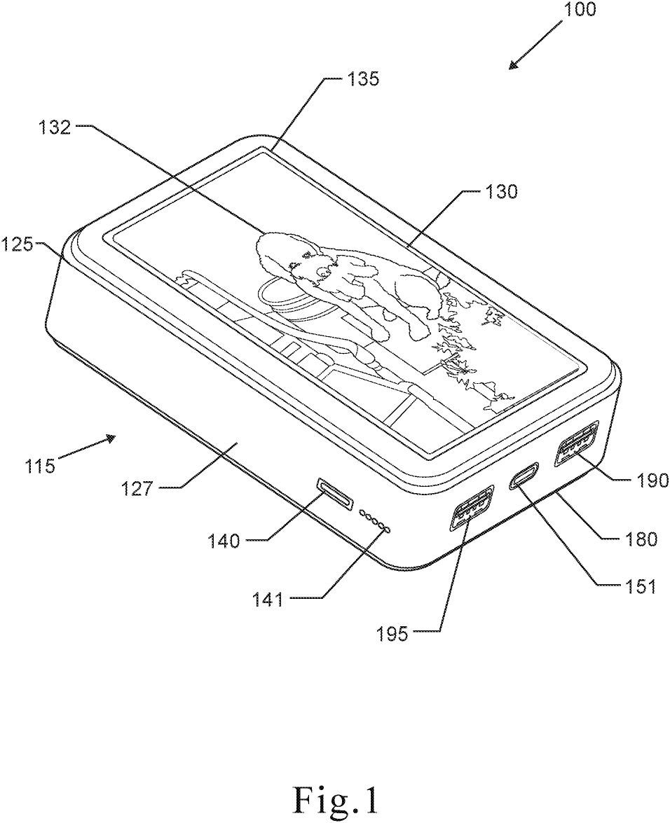

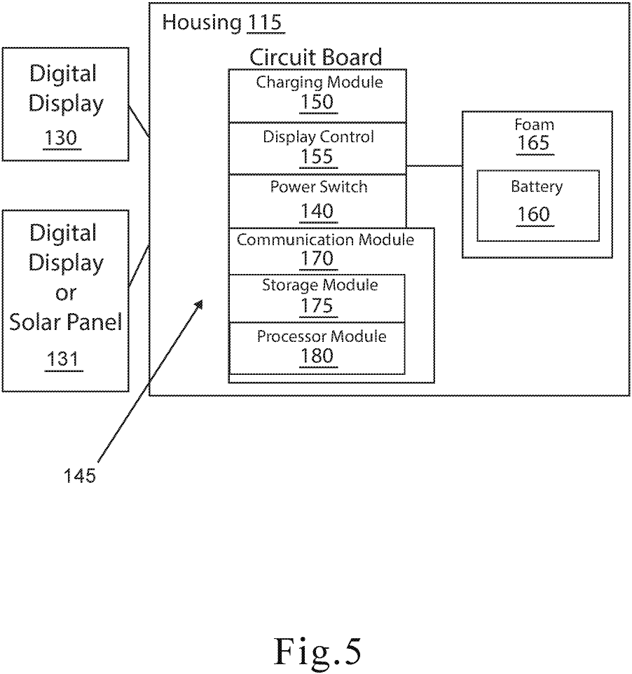

FIG. 1 is an illustration of a perspective view of one embodiment of a portable power bank with a digital display. As shown in FIG. 1, the power bank 100 may comprise a housing 115, a first digital display 130, a first display cover 135, and circuit board 145 (see FIG. 5). The housing 115 may comprise a first or top face 125, a side face 127, and an end face 180.

In one embodiment, the housing 115 may preferably comprise a non-porous material, such as molded plastic, clear molded epoxy, solid molded epoxy, stainless steel, aluminum, and other waterproof materials.

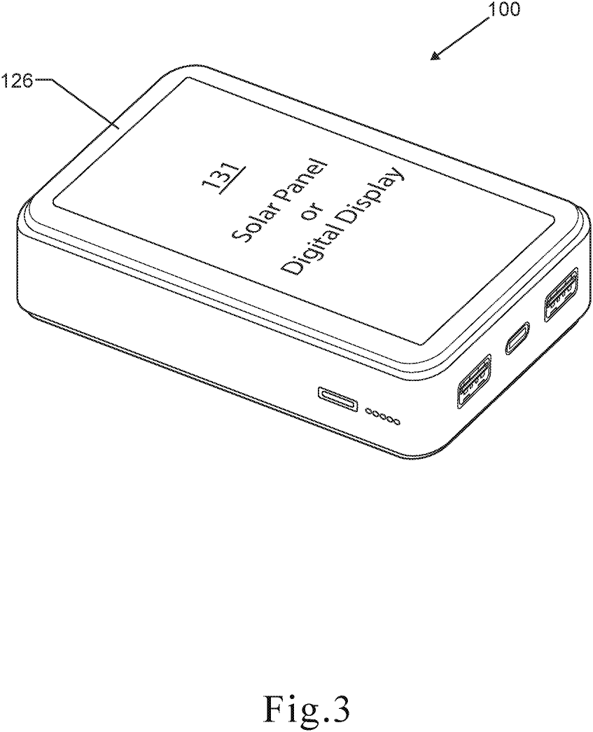

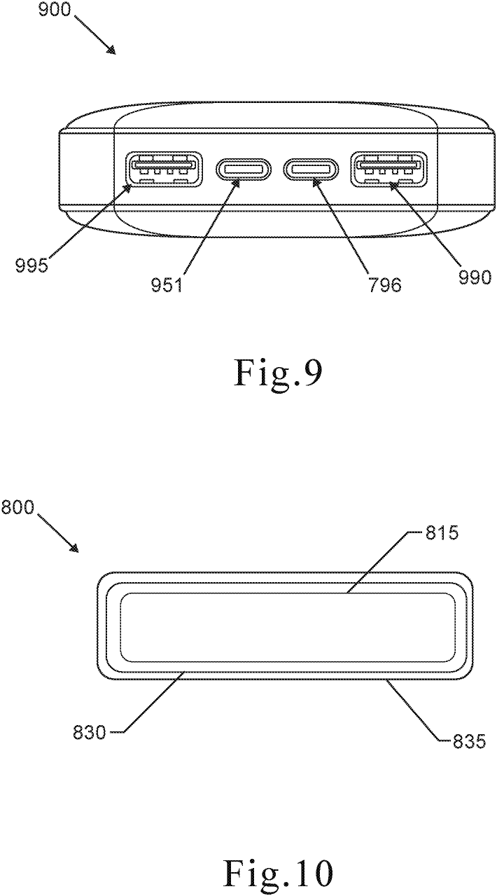

The first digital display 130 may be located on the first face 125. The first digital display 130 may partially, substantially, or completely cover the first face 125. In some embodiments, the first digital display 130 may be configured to cover specific portions of the first face 125, depending on specific design requirements or preferences. The first digital display 130 may be substantially any type of electronic display, including, but not limited to LED screens, SMB LEDs, individual LED diodes, LED diodes in the format of a panel, OLED screens, plasma screens, full array LED screens, EL panels, and the like. In some embodiments, the first digital display 130 may also cover a portion of one or more of the other sides of the housing 115, as shown in FIGS. 3 and 9. In some embodiments, the first digital display 130 may be substantially soft or flexible. In other embodiments, the first digital display 130 may be substantially rigid.

In some embodiments, the first digital display 130 may be partially or completely covered by a first display cover 135. The first display cover 135 may preferably be a partially or completely transparent material, such that the first digital display 130, when active, may be viewable by an observer. As shown in FIG. 1, the digital display 130 may display a data file, such as a photograph, image, or video 132.

The housing 115 may also comprise a circuit board 145 (see FIG. 5). In one embodiment, the circuit board 145 may comprise a charging module 150, display control 155, power switch 140, battery status indicator 141, and communication module 170. The power switch 140 may be accessible from outside the housing 115. The housing 115 contains one or more batteries 160. This may be the power bank battery and/or a separate battery just for the digital display 130. The battery 160 may be protected by or encased in a protective structure 165. In one embodiment, the protective structure 165 may be a fire resistant foam. The battery 160 may be used to power the first digital display 130, as well as components of the circuit board 145, and/or charge other electric devices. The display control 155 may be configured to determine what images, video, or materials are displayed on the first digital display 130 and to generate and send the appropriate signals. The battery status indicator 141 may be configured to relay information relating to status of the battery 160 to the user, such as by differing intensity of a light or color of a light.

The charging module 150 may be a wired or wireless charging module. Power may be supplied to the charging module 150, which may then cause the battery 160 to be charged. If the charging module 150 is a wired charging module, then the charging module 150 may comprise a charging inlet 151 configured in the format of mini-usb, micro-usb, usb-a, usb-c, or substantially any other charging structure. The charging module 150 may be a wireless charging module, such as an inductive wireless charging protocol.

The circuit board 145 may also comprise a communication module 170. The communication module 170 may be configured to communicate with a remote device, such as a smart phone, laptop, desktop, tablet, or other electronic computing device, such that the remote device may send to the power bank 100 instructions and/or commands to cause the first digital display 130 and/or the second digital display 131 to activate, deactivate, or display static or moving images on the first digital display 130 and/or the second digital display 131. The communication module 170 may be a wireless communication module, as preferred, or a wired communication module. In one embodiment, the communication module 170 may receive communication through the charging module 150 if the charging module 150 is a wired charging module. In one embodiment, the communications may comprise one or more electronic signals from a remote electronic device. The electronic signals may comprise one or more data files, one or more instructions, or combinations thereof. The data files may comprise videos, pictures, graphics, information, gifs, other moving or static images, or combinations thereof. In some embodiments, the digital display 130 may display streaming content that is delivered wirelessly to the digital display 130 through the communication module 170.

The circuit board 145 may comprise one or more power outputs 190, 195. The power outputs 190, 195 may be configured to allow power cables to connect to the power bank 100 in order to charge remote devices.

In some embodiments, the power bank 100 may comprise a storage module 175 configured to store images, video, or other materials to be displayed on the first digital display 130. In some embodiments, the storage module 175 may be a part of the circuit board 145, or may be in electronic communication with the circuit board 145 and/or first digital display 130. The storage module 175 may be a solid state memory storage device. The storage module 175 may also comprise a computer processing unit and a video processor, which may allow for more complex use of the first digital display 130.

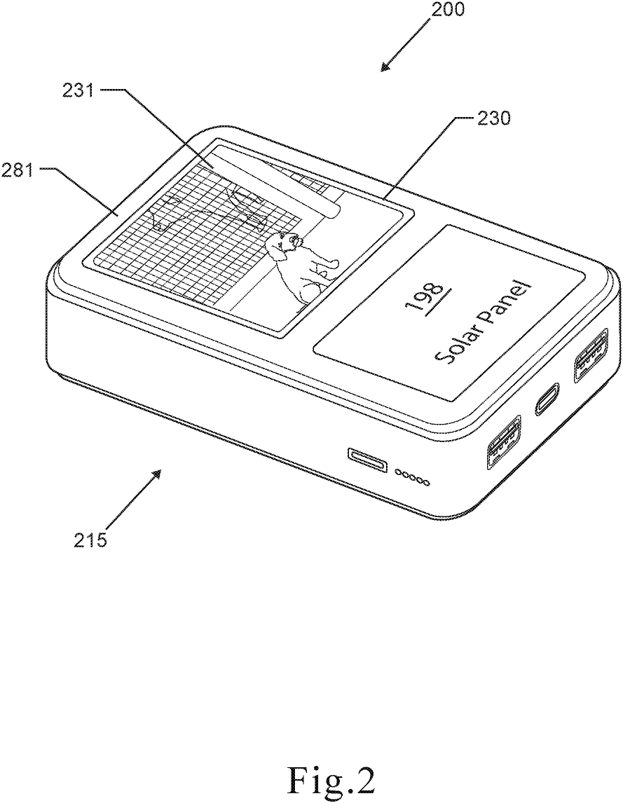

FIG. 2 is an illustration of a perspective view of another embodiment of a portable power bank with a digital display. FIG. 2 shows that portable power bank 200 may comprise a top side or face 281 of housing 215. The housing 215 may comprise a digital display 230 and a solar panel 198 for charging the battery of the power bank 200. FIG. 2 shows that the display 230 may display images or video 231 and does not take up the entire area of top side 281.

FIG. 3 is an illustration of a perspective view of another embodiment of a portable power bank with a digital display. FIG. 3 shows that power bank 100 may comprise a rear side 126 that may comprise a second digital display or solar panel 131. If there is a second digital display 131 it may display the same images or videos, different images or videos, or different portions of the images or videos being shown on display 130.

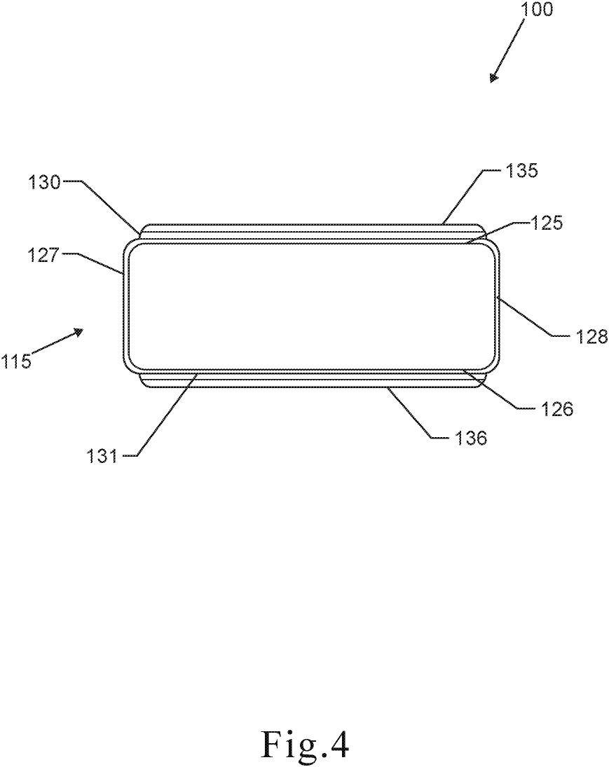

FIG. 4 is an illustration of a cross-section view of one embodiment of a power bank with a digital display. As shown in FIG. 4, the first face 125, first digital display 130, and first display cover 135 may be similar in shape, such that the first digital display 130 is sandwiched between the first face 125 and first display cover 135. In some embodiments, the first display cover 135 may not be present, or may be configured to be removable from the first digital display 130. In other embodiments, the first digital display 130 and first display cover 135 may not be present or may be configured to be removable from the first face 125.

The second face 126, second digital display 131, and second display cover 136 may be similar in shape, such that the second digital display 131 is sandwiched between the second face 126 (rear side) and second display cover 136. In some embodiments, the second display cover 136 may not be present, or may be configured to be removable from the second digital display 131. In other embodiments, the second digital display 131 and second display cover 136 may not be present, or may be configured to be removable from the second face 126.

In one embodiment, the first and second faces 125, 126 may be made of molded plastic, clear molded epoxy, solid molded epoxy, stainless steel, aluminum, and similar waterproof alloys.

In one embodiment, the first and second display covers 135, 136 may be made of a transparent material configured to allow some amount of light to pass through. In a preferred embodiment, the first and second display covers 135, 136 may be waterproof and/or shock resistant.

In some embodiments, the first and/or the second digital displays 130, 131 may be configured to extend to cover one or more of the other sides and ends of the housing 115. In some embodiments, the first digital display 130 may be configured to cover one or more of the first face 125, second face 126, and/or the other sides and ends of housing 115.

FIG. 5 is a diagram of one embodiment of a portable power bank with one or more digital displays. As shown in FIG. 5, the circuit board 145 may comprise the charging module 150, display control 155, power switch 140, and communication module 170. The circuit board 145 may also comprise the battery 160, along with the protective structure 165.

The circuit board 145 may be in electronic communication with the first digital display 130 and/or the second digital display 131, such that the circuit board 145, and its various components, send electronic communications (wired or wireless) to the first digital display 130 and/or the second digital display 131 to cause the first digital display 130 and/or the second digital display 131 to show images, video, and other materials.

In one embodiment, the circuit board 145 may comprise the storage module 175 configured to store the images, video, or other materials to be shown on the digital display.

The battery 160 may be configured, in addition to charging connected electronic devices, to provide power to the circuit board 145, the first digital display 130 and/or the second digital display 131.

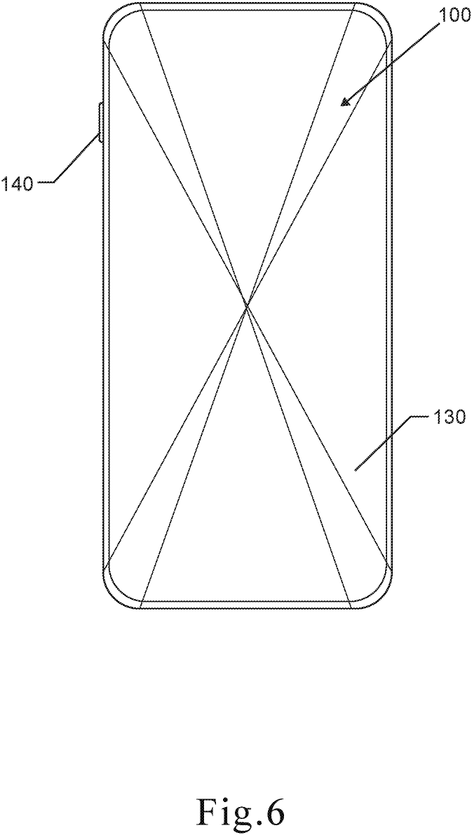

FIG. 6 is an illustration of a top view of one embodiment of a portable power bank. The power bank 100 may comprise the first digital display 130, which may be configured to be substantially similar in shape to a mobile phone, such that images, videos, and other images may be shown in a format already known to the user. FIG. 6 shows the power switch 140, which may be a digital button, analog button, tactile button, or soft key.

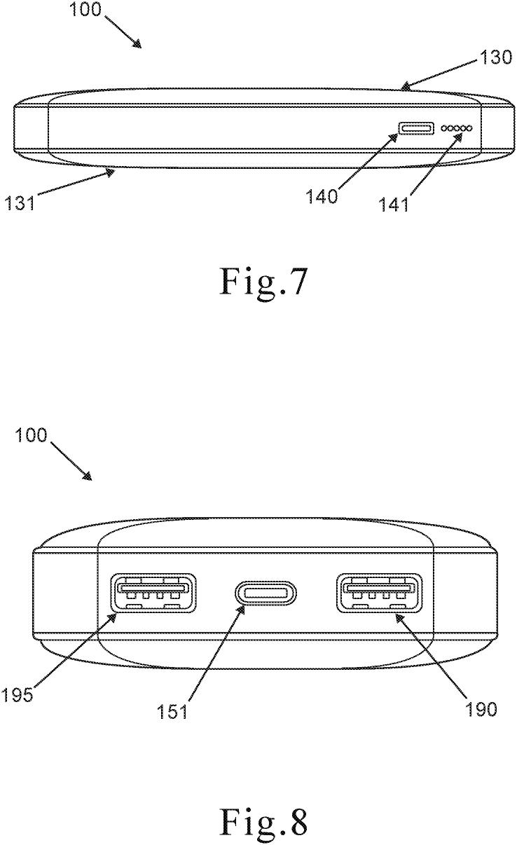

FIG. 7 is an illustration of a side view of one embodiment of the portable power bank 100. In one embodiment, the power switch 140, when pressed or actuated, may automatically cause pre-determined images and/or videos to display on the first digital display 130 and/or second digital display 131. FIG. 7 also shows another embodiment of battery status indicator 141 and is shown a series of lights.

FIG. 8 is an illustration of an end view of one embodiment of the portable power bank. As shown in FIG. 8, the power bank 100 may comprise power outputs 190, 195 and charging inlets 151.

FIG. 9 is an illustration of an end view of another embodiment of the portable power bank. As shown in FIG. 9, a power bank 900 may be substantially similar to the power bank 100 shown in FIG. 8, with the primary difference being that the power bank 900 comprises an additional power output 796. One benefit of having an additional power output 796 is that additional power output formats may be supported on a single power bank 900.

FIG. 10 is an illustration of an end view of another embodiment of the portable power bank. As shown in FIG. 10, the power bank 800 may comprise a housing 815 that is surrounded on at least four faces or sides by a display 830, which may be in turn covered by a display cover 835. In other respects, the power bank 800 may be substantially similar to the power bank 100 shown in FIG. 1. Preferably, the battery status indicator and power switch would be on an end of the power bank 830 rather than a side.

Unless otherwise stated, all measurements, values, ratings, positions, magnitudes, sizes, locations, and other specifications, which set forth in this specification, including in the claims that follow, are approximate, not exact. They are intended to have a reasonable range, which is consistent with the functions to which they relate and with what is customary in the art to which they pertain.

The foregoing description of the preferred embodiment has been presented for the purposes of illustration and description. While multiple embodiments are disclosed, still other embodiments will become apparent to those skilled in the art from the above detailed description, which shows and describes the illustrative embodiments. As will be realized, these embodiments are capable of modifications in various obvious aspects, all without departing from the spirit and scope of the present disclosure. Accordingly, the detailed description is to be regarded as illustrative in nature and not restrictive. Also, although not explicitly recited, one or more additional embodiments may be practiced in combination or conjunction with one another. Furthermore, the reference or non-reference to a particular embodiment shall not be interpreted to limit the scope of protection. It is intended that the scope of protection not be limited by this detailed description, but by the claims and the equivalents to the claims that are appended hereto.

Except as stated immediately above, nothing which has been stated or illustrated is intended or should be interpreted to cause a dedication of any component, step, feature, object, benefit, advantage, or equivalent to the public, regardless of whether it is or is not recited in the claims.

What is claimed is:

1. A portable power bank comprising:
a housing;
a power source; and
a first digital display;
wherein said first digital display is configured to display one or more data files; and
wherein said power source is configured to charge one or more electronic devices connected to said portable power bank.

2. The power bank of claim 1, further comprising a first display cover;
wherein said first display cover is configured to protect said first digital display by substantially covering said first digital display; and
wherein said first display cover is transparent.

3. The power bank of claim 1, further comprising a second digital display.

4. The power bank of claim 1, further comprising a circuit board;
wherein said circuit board comprises a charging module, a display control, and a power switch;
wherein said circuit board is powered by said power source.

5. The power bank of claim 4, wherein said circuit board comprises a wireless communication module.

6. The power bank of claim 5, wherein said wireless communication module is configured to receive one or more electronic signals from a remote electronic device.

7. The power bank of claim 6, wherein said one or more electronic signals comprise one or more of said one or more data files, one or more instructions, and combinations thereof;
wherein said one or more data files comprise one or more of the following:
videos, pictures, images, graphics, information, gifs, and combinations thereof.

8. The power bank of claim 1, wherein said power source is substantially located within said housing; and
wherein said circuit board is substantially located within said housing.

9. The power bank of claim 8, wherein said power source is a battery.

10. The power bank of claim 9, wherein said battery is substantially enclosed in fireproof foam.

11. The power bank of claim 7, wherein said one or more instructions are configured to cause said one or more data files to be displayed on said first digital display.

12. The power bank of claim 1, wherein said housing has a plurality of sides comprising at least a first side and a second side;
wherein said first digital display at least partially covers said first side.

13. The power bank of claim 12, wherein said first digital display substantially cover said first side and said second side.

14. The power bank of claim 12, wherein said second side is at least partially covered by a second digital display.

15. The power bank of claim 12, wherein said plurality of sides comprises said first side, said second side, a third side, and a fourth side;
wherein said first digital display substantially covers said first side, said second side, said third side, and said fourth side.

16. The power bank of claim 12, further comprising at least one solar panel; wherein said at least one solar panel is configured to charge said power source.

17. A power bank comprising:
a housing;
a power source;
a circuit board;
a first digital display; and
a display cover;
wherein said housing comprises at least a first side and a second side;
wherein said first digital display covers at least a portion of said first side;
wherein said display cover is configured to protect said first digital display by substantially covering said first digital display;
wherein said display cover is transparent;
wherein said circuit board comprises a charging module, a display control, a wireless communication module, and a power switch;
wherein said circuit board and said first digital display are powered by said power source;
wherein said wireless communication module is configured to receive one or more electronic signals from a remote electronic device;
wherein said one or more electronic signals comprise one or more of one or more data files, one or more instructions, and combinations thereof;
wherein said one or more data files comprise one or more of the following:
videos, pictures, images, graphics, information, gifs, and combinations thereof;
wherein said power source is substantially contained within said housing;
wherein said circuit board is substantially contained within said housing;
wherein said power source is a battery; and
wherein said one or more instructions are configured to cause said one or more data files to be displayed on said first digital display.

18. The power bank of claim 17, wherein said housing has a plurality of sides comprising at least a first side and a second side;
wherein said first digital display substantially covers said first side.

19. The power bank of claim 18, wherein said second side is at least partially covered by a second digital display.

20. The power bank of claim 18, wherein said plurality of sides comprises said first side, said second side, a third side, and a fourth side;
wherein said first digital display substantially covers said first side, said second side, said third side, and said fourth side.
